(19) United States
(12) Patent Application Publication
(10) Pub. No.: US 2025/0140517 A1
(43) Pub. Date: May 1, 2025

(54) MULTIPLE CHARGED PARTICLE BEAM WRITING APPARATUS AND MULTIPLE CHARGED PARTICLE BEAM WRITING METHOD

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 18/929,787

(22) Filed: Oct. 29, 2024

(30) Foreign Application Priority Data
Nov. 1, 2023 (JP) 2023-187857

(51) Int. Cl. H01J 37/302; H01J 37/04; H01J 37/317

(52) U.S. Cl. CPC H01J 37/3023; H01J 37/045; H01J 37/3177; H01J 2237/30472

(57) ABSTRACT

In one embodiment, a multiple charged particle beam writing apparatus includes an emitter configured to emit multiple-beam of charged particles, and an irradiation time controller configured to control an irradiation time of each of a plurality of beams included in the multiple-beam. The plurality of beams are classified into a plurality of groups including a first group and a second group. The irradiation time controller controls beams in the first group to be ON simultaneously at a first timing, and to be OFF after lapse of an irradiation time of each beam, and controls beams in the second group to be ON based on the irradiation time of each beam, and to be OFF simultaneously at a second timing.

### CROSS REFERENCE TO RELATED APPLICATION

This application is based upon and claims benefit of priority from the Japanese Patent Application No. 2023-187857, filed on Nov. 1, 2023, the entire contents of which are incorporated herein by reference.

### FIELD

The present invention relates to a multiple charged particle beam writing apparatus and a multiple charged particle beam writing method.

### BACKGROUND

As LSI circuits are increasing in density, the required linewidths of circuits used in semiconductor devices become finer year by year. To form a desired circuit pattern of a semiconductor device, a method is employed in which an original pattern formed with high precision by patterning a light shielding film on quartz or a light adsorbing film on reflective film is transferred to a wafer in a reduced manner by using a reduced-projection exposure apparatus. To produce such high-precision original patterns, so-called electron beam lithography technology is used, in which patterns are formed by exposing resist with an electron beam writing apparatus. Also, a so-called wafer direct writing technique is used, in which a pattern is formed by exposing the resist directly applied on the wafer by an electron beam.

A writing apparatus that uses a multiple-beam can emit more beams at one time than a writing apparatus that performs writing with a single electron beam, thus the throughput can be significantly improved. As a form of multiple-beam writing apparatus, a multiple-beam writing apparatus using a blanking aperture array substrate (blanking plate) forms a multiple-beam (a plurality of electron beams) by passing an electron beam emitted from single electron gun through a shaping aperture array member having a plurality of openings. The blanking aperture array substrate is disposed beneath the shaping aperture array member. The blanking aperture array substrate has electrode pairs for individually deflecting beams, and includes an opening for beam passage between each electrode pair. Blanking deflection is performed to turn off a passing electron beam by fixing one of each electrode pair (blanker) to the ground potential, and switching the other electrode between the ground potential and another potential. The optical column of a multiple-beam writing apparatus is configured to block an electron beam deflected by a blanker to set it OFF, and to allow an electron beam not deflected to be radiated onto a sample as an on-beam.

When writing is performed with a multiple-beam, the total beam current amount used for exposure can be increased, but increasing the total beam current amount may cause writing accuracy deterioration due to the Coulomb effect. For example, due to repulsion between the electrons, positional deviation or focus deviation of multiple-beam on a sample surface may occur. The Coulomb effect occurs at a location where the density of electron beam is high in the optical system. Thus, the rate of occurrence of the Coulomb effect is high at a cross-over downstream of the blanking aperture array in the beam travel direction and in the vicinity of the sample surface of an objective optical system, where the beam array is reduced. Therefore, the amplitude of the Coulomb effect varies depending on the amount of the current of on-beam, specifically, the amount of current of the beam that is controlled to ON by the blanking aperture array substrate to reach the sample surface.

For the Coulomb effect, the measures (see Japanese Unexamined Patent Application Publication No. 2007-329220) to reduce the total amount of the current of on-beam in multiple-beam irradiation and the measures (see U.S. Patent Application Publication No. 2010/0124722) to reduce variation in the amount of on-beam current have been proposed. The measures to reduce the total amount of the current of on-beam is effective when the time during which the beam is not set ON in a shot cycle is longer than the time during which the beam is set ON; however, when the writing system is optimized and the time during which the beam is not set ON is reduced, the effect is smaller. The measures to reduce variation in the amount of on-beam current are such that one exposure process is divided into multiple exposure processes with the same time, and the beam ON intervals are dispersed on the time axis so that the variation in the amount of on-beam current in the exposure processes is reduced. However, this method has a problem in that the volume of data to be transferred to the blanking plate increases due to exposure gradation control.

### BRIEF DESCRIPTION OF THE DRAWINGS

FIG. 1 is a schematic view of a multiple charged particle beam writing apparatus according to an embodiment of the present invention.

FIG. 2 is a plan view of a shaping aperture array plate.

FIG. 3 is a cross-sectional view illustrating the configuration of a blanking plate.

FIG. 4 is a schematic configuration view of the blanking plate.

FIG. 5 is a configuration view of an I/O circuit and a cell array circuit.

FIG. 6 is a schematic configuration view of an individual blanking mechanism.

FIG. 7A is a graph showing the output of a count-up circuit, FIG. 7B is a graph showing ON/OFF of simultaneous on-beam, FIG. 7C is a graph showing the output of a count-down circuit, and FIG. 7D is a graph showing ON/OFF of simultaneous off-beam.

FIGS. 8A to 8C are views illustrating an example of group classification of beam array.

FIG. 9 is a flowchart for explaining a writing method.

FIG. 10 is a view for explaining a writing operation.

FIG. 11 is a schematic configuration view of an individual blanking mechanism.

FIG. 12A is a graph showing the output of the count-up circuit, FIG. 12B is a graph showing ON/OFF of simultaneous off-beam, and FIG. 12C is a graph showing a shot enable signal.

FIG. 13A is a graph showing the output of the count-up circuit, FIG. 13B is a graph showing ON/OFF of simultaneous on-beam, FIG. 13C is a graph showing the output of the count-down circuit, and FIG. 13D is a graph showing ON/OFF of simultaneous off-beam.

FIGS. 14A to 14C are graph showing the output of the count-up circuit, and FIGS. 14D to 14F are graph showing ON/OFF of beam.

FIGS. 15A to 15C are views illustrating an example of group classification of beam array.

### DETAILED DESCRIPTION

In one embodiment, a multiple charged particle beam writing apparatus includes an emitter configured to emit multiple-beam of charged particles, and an irradiation time controller configured to control an irradiation time of each of a plurality of beams included in the multiple-beam. The plurality of beams are classified into a plurality of groups including a first group and a second group. The irradiation time controller controls beams in the first group to be ON simultaneously at a first timing, and to be OFF after lapse of an irradiation time of each beam, and controls beams in the second group to be ON based on the irradiation time of each beam, and to be OFF simultaneously at a second timing.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

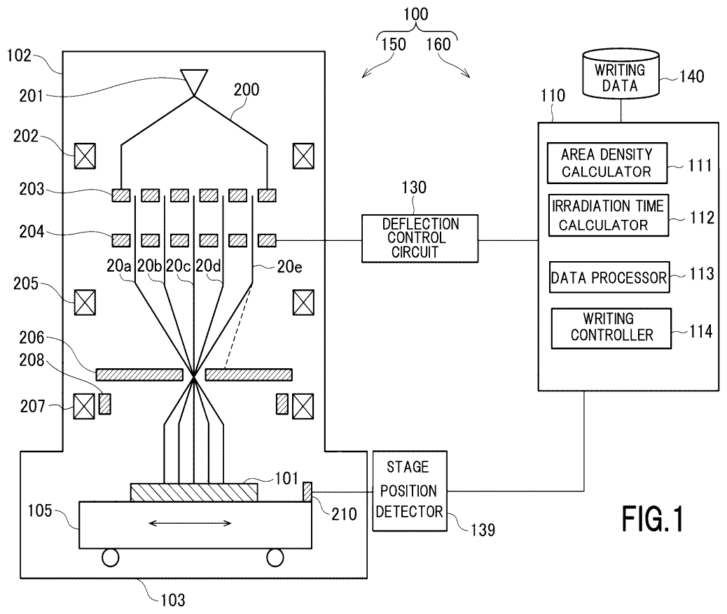

FIG. 1 is a schematic view of a writing apparatus according to an embodiment. As illustrated in FIG. 1, a writing apparatus 100 includes a writer 150 and a controller 160. The writing apparatus 100 is an example of a multiple charged particle beam writing apparatus. The writer 150 includes an electronic column 102 and a writing chamber 103. In the electronic column 102, an electron gun 201, an illumination lens 202, a shaping aperture array plate 203, a blanking plate 204, a reduction lens 205, a limiting aperture member 206, an objective lens 207, and a deflector 208 are disposed.

In the writing chamber 103, an XY stage 105 is disposed. A substrate 101 as a writing target is disposed on the XY stage 105. The substrate 101 is, for example, a mask blank or a semiconductor substrate (silicon wafer). A mirror 210 for position measurement is disposed on the XY stage 105.

The controller 160 includes a control computer 110, a deflection control circuit 130, a stage position detector 139, and a storage 140. The storage 140 receives input of writing data from the outside, and stores it. The writing data defines information on a plurality of figure patterns for describing a pattern to be formed on the substrate 101. Specifically, for each figure pattern, the figure code, the coordinates, and the size are defined.

The control computer 110 includes an area density calculator 111, an irradiation time calculator 112, a data processor 113 and a writing controller 114. Each component of the control computer 110 may be comprised of hardware such as an electric circuit, or software such as programs that execute these functions. Alternatively, the component may be comprised of a combination of hardware and software.

The stage position detector 139 emits a laser to the mirror 210, receives reflected laser from the mirror 210, and detects the position of the XY stage 105 by a laser interference method.

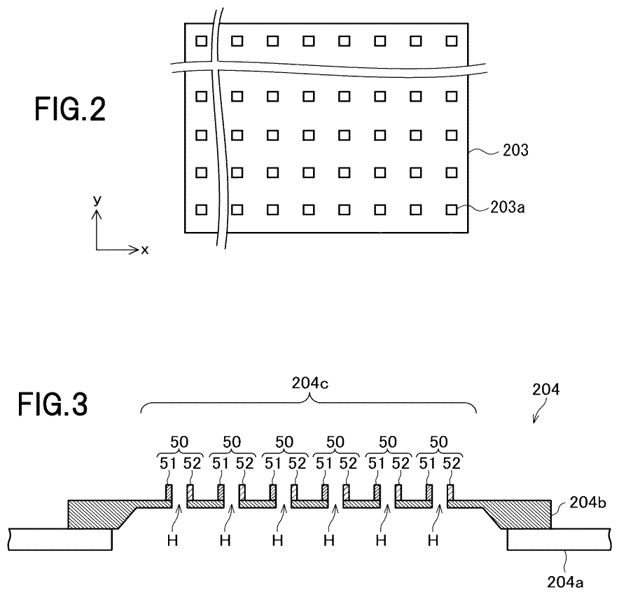

FIG. 2 is a conceptual view illustrating the configuration of the shaping aperture array plate 203. As illustrated in FIG. 2, in the shaping aperture array plate 203, a plurality of openings 203a are formed in a vertical direction (y direction) and a horizontal direction (x direction) with a predetermined arrangement pitch. The openings 203a are preferably formed in rectangular or circular shapes having the same dimensions. Part of an electron beam 200 passes through each of these multiple openings 203a, thereby forming multiple-beam 20a to 20e.

As illustrated in FIG. 3, the blanking plate 204 includes a support stand 204a, and a semiconductor substrate 204b composed of silicon provided on the support stand 204a. The central portion of the semiconductor substrate 204b is thinly chopped from the back surface side, and fabricated as a membrane region 204c with a thin film thickness. The periphery surrounding the membrane region 204c is an outer peripheral region with a thick film thickness, and the semiconductor substrate 204b is held on the support stand 204a on the back surface of the outer peripheral region. The central portion of the support stand 204a is open, and the position of the membrane region 204c is located at the opened region of the support stand 204a.

In the membrane region 204c of the blanking plate 204, passage holes H are formed corresponding to the arrangement positions of the openings 203a of the shaping aperture array plate 203. In each passage hole H, a blanker 50 is disposed, which consists of a set of two electrodes 51, 52 as a pair. One of a multiple-beam passes through between an electrode pair and a passage hole H. The blanker 50 earths one electrode 52 to maintain it at the ground potential, and switches the other electrode 51 to the ground potential or a potential other than the ground potential, thereby switching between ON and OFF of deflection of a beam passing through a passage hole H. When the blanker 50 does not deflect a beam, the beam is set ON. When the blanker 50 deflects a beam, the beam is set OFF. In this manner, a plurality of blankers 50 perform blanking deflection on corresponding beams in the multiple-beam which has passed through the plurality of openings 203a of the shaping aperture array plate 203.

The electron beam 200 emitted from the electron gun 201 (emitter) illuminates an area including all openings 203a of the shaping aperture array plate 203 by the illumination lens 202. The electron beam 200 passes through the plurality of openings 203a of the shaping aperture array plate 203, thereby forming e.g., a plurality of rectangular electron beams (multiple-beam) 20a to 20e.

The multiple-beam 20a to 20e pass through corresponding blankers 50 of the blanking plate 204. The blankers 50 each perform blanking deflection selectively on the beam to be OFF individually among the passing electron beams. The blanker 50 does not perform blanking deflection on the beam to be ON. The multiple-beam 20a to 20e which have passed through the blanking plate 204 are reduced by the reduction lens 205, and travel to a central opening formed in the limiting aperture member 206.

A beam controlled to be OFF is deflected by the blanker 50, passes a trajectory outward of the opening of the limiting aperture member 206, thus is blocked by the limiting aperture member 206. In contrast, a beam controlled to be ON is not deflected by the blanker 50, thus passes through the opening of the limiting aperture member 206. The trajectory of beam is adjusted in advance by an alignment coil (not illustrated) so that a beam controlled in beam-on state is located within the opening of the limiting aperture member 206. In FIG. 1, the trajectory of the multiple-beam is adjusted so that the multiple-beam in beam-on state converges to one point at the position of the limiting aperture member 206, and it is preferable to adjust the alignment coil so that this point is located in the central portion of the opening of the limiting aperture member 206. In this manner, ON/OFF state of each beam in the multiple-beam is controlled by a combination of ON/OFF operation of deflection of the blanker 50 and blocking of the beam by the limiting aperture. In other words, blanking control is performed. The blanking plate 204 has the function as (part of) an irradiation time controller that controls the irradiation time of each beam in the multiple-beam.

The limiting aperture member 206 blocks the beams that are deflected by multiple blankers 50 to achieve beam-off state. The multiple-beam for one shot is formed by the beam which has passed through the limiting aperture member 206 since beam-on until beam-off is achieved.

The multiple-beam which has passed through the limiting aperture member 206 is focused by the objective lens 207, and forms a pattern image on the substrate 101 with a desired reduction factor. Ideally, the multiple-beam is arranged on the substrate 101 with the pitch which is the product of the arrangement pitch of the plurality of openings 203a of the shaping aperture array member 203 and the above-mentioned desired reduction factor. The beams (the entire beams in beam-on state in the multiple-beam) which have passed through the limiting aperture member 206 are collectively deflected by the deflector 208 in the same direction, and emitted to a desired position on the substrate 101 with a focus on the surface of the substrate 101.

The irradiation of the substrate 101 with multiple-beam is possible even when the XY stage 105 is in a still state or is continuously moved. When the XY stage 105 is continuously moved, the amount of change in the stage position is measured by the stage position detector 139, and using the measurement result, the position of the multiple-beam is continuously changed using the deflector 208 so as to follow the movement of the XY stage 105. This is called stage tracking deflection. The position of the multiple-beam on the substrate 101 can be fixed by the stage tracking deflection. When writing is performed, at least during irradiation of the substrate 101 with a beam, stage tracking deflection is performed so that the position of each beam in the multiple-beam on the substrate 101 is controlled to be fixed.

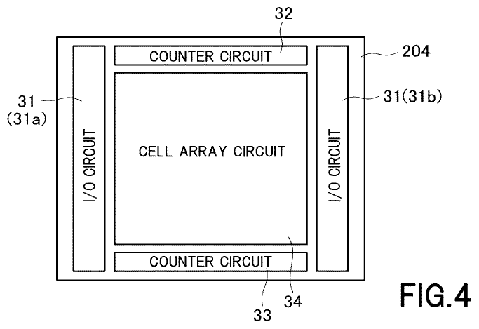

As illustrated in FIG. 4, the blanking plate 204 that performs blanking control on each beam in the multiple-beam includes an I/O circuit 31, counter circuits 32, 33 and a cell array circuit 34.

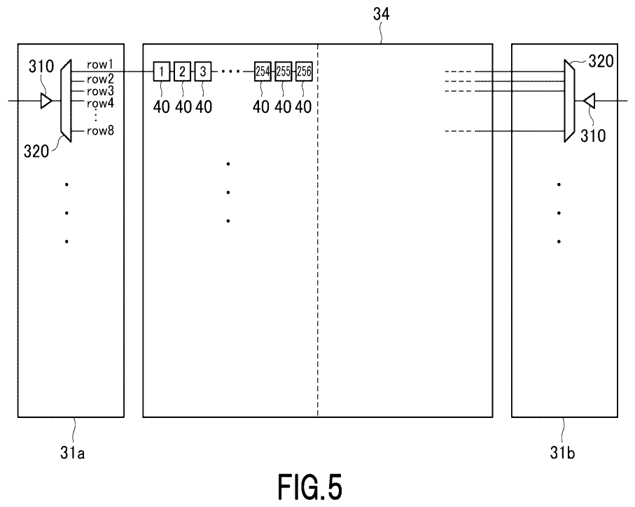

As illustrated in FIG. 5, the cell array circuit 34 is provided with a plurality of cells that form individual blanking mechanisms 40 (individual blanking control circuit). One individual blanking mechanism 40 corresponds to one blanker 50. The I/O circuit 31 outputs the data received from the deflection control circuit 130 to the cell array circuit 34. For example, the I/O circuit 31 includes an I/O circuit 31a disposed on one side of the cell array circuit 34 and configured to output data to the individual blanking mechanisms 40 in the left half of the cell array circuit 34; and an I/O circuit 31b disposed on the other side of the cell array circuit 34 and configured to output data to the individual blanking mechanisms 40 in the right half of the cell array circuit 34.

The I/O circuit 31 is provided with a plurality of selectors 320 (demultiplexers). Each selector 320 receives via a receiver 310 irradiation time control data that defines the irradiation time for each beam shot, and outputs the irradiation time control data from a corresponding output line. Each output line is connected in series to a plurality of individual blanking mechanisms 40.

For example, the selector 320 has eight output line row1 to row8, and each output line is connected to 256 individual blanking mechanisms 40. Providing each of the I/O circuits 31a, 31b with 64 selectors 320 makes it possible to transfer the irradiation time control data to 512×512 individual blanking mechanisms 40 in the cell array circuit 34.

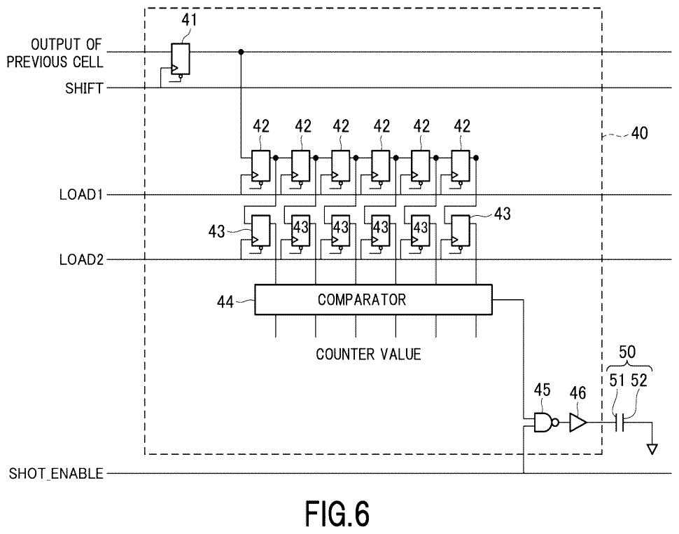

As illustrated in FIG. 6, the individual blanking mechanism 40 includes a shift register 41, buffers 42, registers 43, a comparator 44, a NAND circuit 45 and an amplifier 46. Each register 41 transfers the data output from the shift register of the previous stage cell to the shift register of the subsequent stage cell in accordance with a clock signal (SHIFT).

A plurality of buffers 42 are provided, and store irradiation time data for the cell use in accordance with a clock signal (LOAD1), the irradiation time data being output from the shift register 41. For example, when the irradiation time control data is 6 bits, 6 buffers 42 are provided, and one buffer 42 holds a value of 1 bit.

The registers 43 are provided as many as the buffers 42. After the value of each bit of the irradiation time control data is transferred to a corresponding one of the buffers 42, each register 43 fetches and holds the output value of the corresponding buffer 42 in accordance with a clock signal (LOAD2). After the irradiation time control data is fetched in the registers 43, the shift register 41 and the buffers 42 transfer the irradiation time control data for the next shot. Transfer of the irradiation time control data from the receiver 310 to the buffers 42 is quickly performed, and if the transfer is completed in a time shorter than the shot time, transfer of the irradiation time control data is completed until the shot is finished, thus after the shot is finished, the next shot can be started without waiting for transfer of the irradiation time control data.

As described above, the blanking plate 204 can transfer the irradiation time control data to the individual blanking mechanism 40. After the irradiation time control data is held in the registers 43, blanking control is performed using the irradiation time control data held in the registers 43, specifically, blanking control is performed, which sets the beam to be in ON state for the time specified in the irradiation time control data.

The comparator 44 (comparator) compares the bit string of irradiation time control data Dt output from the set of registers 43 with the bit string of counter value C output from the counter circuit 32 or 33, and outputs High when the irradiation time control data Dt≥the counter value C, or outputs Low when the irradiation time control data Dt<the counter value C.

The output signal of the comparator 44, and shot enable signal (SHOT_ENABLE) are input to the NAND circuit 45. The output signal of the NAND circuit 45 is provided to an electrode 51 of the blanker 50 via the amplifier 46 (driver amplifier).

When the output signal of the comparator 44 and the shot enable signal are both High, the output of NAND circuit 45 becomes Low, the electrode 51 and the electrode 52 have the same potential, and the blanker 50 does not deflect the beam, thus the beam is set ON. When at least one of the output signal of the comparator 44 and the shot enable signal is Low, the output of NAND circuit 45 becomes High, the electrode 51 and the electrode 52 have different potentials, and the blanker 50 deflects the beam, thus the beam is set OFF.

The shot enable signal is input to the NAND circuits 45 of all individual blanking mechanisms 40, thus all beams can be set OFF by setting the shot enable signal to Low.

With the shot enable signal maintained at High, ON/OFF of the beam is switched by the output of the comparator 44. Specifically, when the irradiation time control data Dt≥the counter value C, the beam is set ON, and when the irradiation time control data Dt<the counter value C, the beam is set OFF.

In the present embodiment, a count-up circuit in which the counter value increases with time at a constant rate, and a count-down circuit in which the counter value gradually decreases with time at a constant rate are provided. For example, the counter circuit 32 functions as a count-up circuit, and the counter circuit 33 functions as a count-down circuit. A plurality of cells (individual blanking mechanisms 40) in the cell array circuit 34 are classified into two groups, group A and group B, a counter value for counting up is input to the comparators 44 of the individual blanking mechanisms 40 in group A (first group), and a counter value for counting down is input to the comparators 44 of the individual blanking mechanisms 40 in group B (second group).

The shot operation is performed as follows. Before the shot operation is started, the shot enable signal is set to Low, and all beams are OFF regardless of the values of the registers 43. In this state, the irradiation position of the multiple-beam on the sample 101, in other words, the position of the multiple-beam when the beam is ON is set to a desired position by the deflector 208. In addition, the irradiation time data is set to the registers. When both settings are completed, simultaneously with switching the shot enable signal to High, the counter value is reset to start the count operation of the counter, and the shot operation is started. During the shot operation, ON, OFF states of the beam are switched by the values of the registers and the value of the counter, and the beam is controlled to be ON for the time specified in the irradiation time data. When the counter value reaches a maximum value, the count operation of the counter is stopped, and the shot enable signal is set to Low. Thus, all beams are set OFF regardless of the values of the registers. At this point, the shot operation is completed, and the shot operation for the next shot is started. Note that during the shot operation of a shot, all or part of the irradiation time data for the next shot may be transferred.

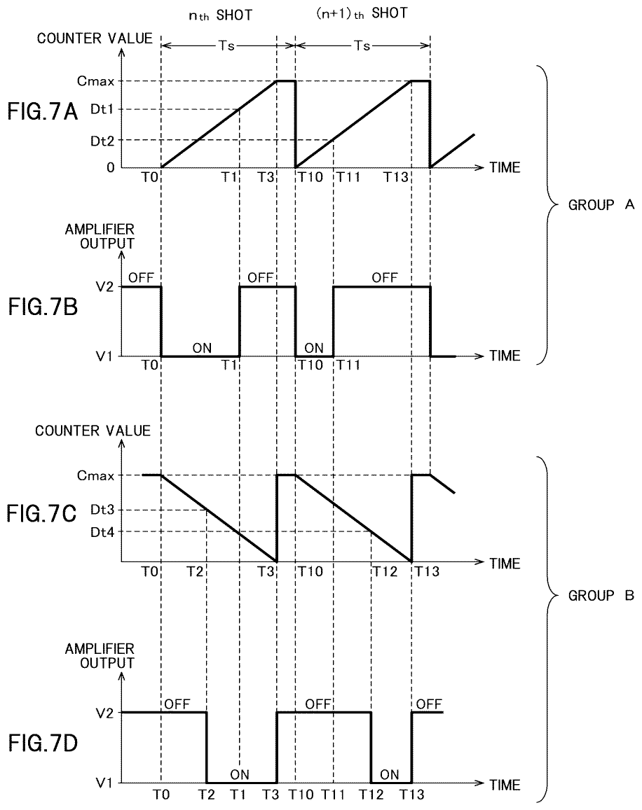

FIG. 7A shows the change in the counter value input to the comparators 44 in group A. At time T0, the shot operation is started, the counter is reset, and the counter value is set to 0, thus the counter operation is started. The counter value increases at a constant rate from time T0 to time T3, and the counter value reaches a predetermined maximum value Cmax at time T3, then the counter operation is stopped. In the interval from time T3 to time T10, the counter value is constant at the predetermined maximum value Cmax. In the interval from time T3 to time T10, positioning of the beam for the next shot is performed. Furthermore, all or part of transfer of the irradiation time data for the next shot may be performed. At time T10, the next shot operation is started, the counter is reset, and the counter value is set to 0, thus the counter operation is started. From time T10 to time T13, the counter value increases from 0 to the maximum value Cmax at a constant rate. Time Ts from start time T0 of the nth shot to start time T10 of the (n+1)th shot is the cycle time of one shot cycle.

FIG. 7B shows an example of the output of the amplifier 46 that controls one beam included in group A. When the irradiation time control data for the nth shot is Dt1, and the irradiation time control data for the (n+1)th shot is Dt2, as illustrated in FIG. 7B, from time T0 to time T1 during which the counter value is Dt1 or less, the output of the amplifier 46 is Low (voltage V1), and the beam is in ON state. In the interval from time T1 to time T10, the output of the amplifier 46 is High (voltage V2), and the beam is in OFF state. As described above, in the case where one of an electrode pair (blanker) is fixed to the ground potential, when the output voltage V1 of the amplifier 46 that controls the potential of the other electrode is 0 V, in other words, when the output potential of the amplifier 46 is the ground potential, the beam is in ON state.

When the counter value is reset to 0 at time T10, the output of the amplifier 46 becomes Low, and the beam is set ON. In the interval from time T10 to time T11 during which the counter value is Dt2 or less, the output of the amplifier 46 is Low (voltage V1), and the beam is in ON state. When the counter value exceeds Dt2, the beam is set OFF.

Like this, in the individual blanking mechanisms 40 in group A, the beam is ON at the start of a shot cycle, and when the counter value of the counter serving as a count-up circuit exceeds the irradiation time data, the beam is set OFF. In other words, it can be stated that the beams in group A are “simultaneous on-beams” that are simultaneously set ON at the start of a shot cycle.

FIG. 7C shows the change in the counter value input to the comparators 44 in group B. From time T0 to time T3, the counter value decreases at a constant rate and after the counter value becomes 0 at time T3, the count value is reset, and set to the predetermined maximum value Cmax. Synchronously, the count operation of the counter is stopped. Therefore, in the interval from time T3 to time T10, the count value remains at Cmax. At time T10, the next shot cycle is started, and from time T10 to time T13, the count operation of the counter is performed, and the counter value decreases at a constant rate.

FIG. 7D shows an example of the output of the amplifier 46 that controls one beam included in group B. When the irradiation time data for the nth shot is Dt3, and the shot time data for the (n+1)th shot is Dt4, as illustrated in FIG. 7D, from time T0 to time T2 during which the counter value is greater than Dt3, the output of the amplifier 46 is High (voltage V2), and the beam is in OFF state. When the counter value becomes Dt3 or less at time T2, the output of the amplifier 46 becomes Low (voltage V1), and the beam is ON. In the interval from time T2 to time T3, the output of the amplifier 46 is Low (voltage V1), and the beam is in ON state. When the counter value is reset to Cmax at time T3, the output of the amplifier 46 becomes High, and the beam is switched to OFF.

In the interval from time T3 to time T12 during which the counter value is greater than Dt4, the output of the amplifier 46 is High (voltage V2), and the beam is in OFF state. When the counter value becomes Dt4 or less at time T12, the output of the amplifier 46 becomes Low (voltage V1), and the beam is set ON. In the interval from time T12 to time T13, the output of the amplifier 46 is Low (voltage V1), and the beam is in ON state. When the counter value becomes 0 at time T13, and the counter is reset and set to Cmax, the output of the amplifier 46 becomes High, and the beam is switched to OFF.

Like this, in the individual blanking mechanisms 40 in group B, when the counter value for counting down decreases to the value of the irradiation time control data, the beam is set ON, and at the timing when the counter value is reset, the beam is set OFF. In other words, it can be stated that the beams in group B are “simultaneous off-beams” that are simultaneously set OFF at the time of reset of the counter value.

As illustrated in FIG. 7B, FIG. 7D, the time interval when the beam is ON in one shot cycle differs between the simultaneous on-beams in group A and the simultaneous off-beams in group B. For example, in the nth shot, both beams illustrated in FIG. 7B, FIG. 7D are ON between times T2 and T1, but before and after the times, only one of the beams is ON. In the (n+1)th shot, counter values Dt2, Dt4 corresponding to the shot time are half or less than the maximum value Cmax of the counter value, thus the time T10 to T11 during which the beams in group A are ON does not overlap with the time T12 to T13 during which the beams in group B are ON, thus both beams are not ON simultaneously.

In this manner, a plurality of beams included in the multiple-beam are controlled by classifying the plurality of beams into groups of simultaneous on-beams and simultaneous off-beams, thus the average value of the total value of on-beam current in a period during which the beams are ON can be decreased so that the influence of the Coulomb effect can be reduced and the writing accuracy can be improved.

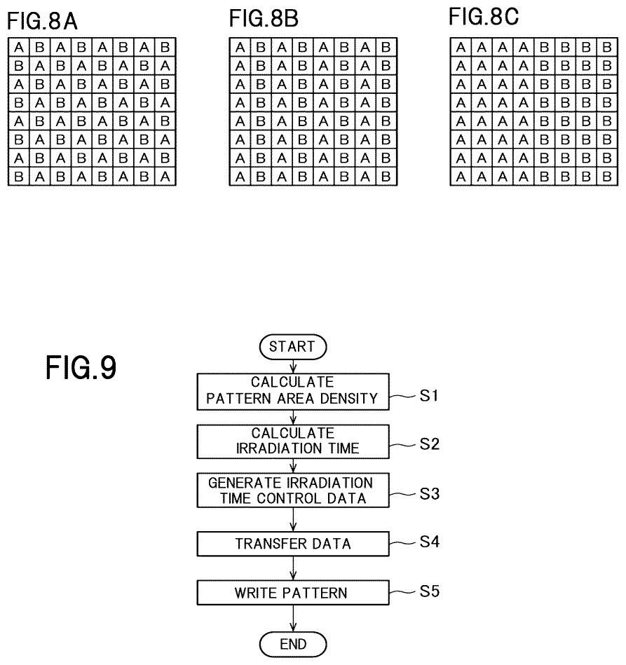

For example, half of the multiple-beam is classified as simultaneous on-beams (group A), and the remaining half is classified as simultaneous off-beams (group B). An example of classification of the beams is shown in FIG. 8A to FIG. 8C. For illustration purposes, FIG. 8A to FIG. 8C illustrate 8×8 beam arrays. It is preferable to classify the beams so that deviation of the beam current of on-beam does not occur. Therefore, as shown in FIG. 8A, FIG. 8B, it is preferable that the beams in group A, group B are classified so as to be alternately disposed rather than being classified as shown in FIG. 8C. The groups of beams may be alternately disposed rather than the beams of different groups being alternately disposed. For example, when the number of beams is 512×512, the meshes in FIG. 8A to FIG. 8C may be expanded to 512×512 and classified; however, 8×8 sets may be formed where one set is 32×32 beams, and as in FIG. 8A to FIG. 8C, a class of 8×8 sets may be classified with a unit of set.

The beams in group A are controlled as the “simultaneous on-beams”, and the beams in group B are controlled as the “simultaneous off-beams”. A counter value output from the counter circuit 32 that functions as a count-up circuit is input to the comparators 44 of the individual blanking mechanisms 40 in group A. A counter value output from the counter circuit 33 that functions as a count-down circuit is input to the comparators 44 of the individual blanking mechanisms 40 in group B.

Next, the pattern writing method according to the present embodiment will be described with reference to the flowchart shown in FIG. 9. In a pattern area density calculation process (step S1), the area density calculator 111 virtually divides a writing region of the substrate 101 into a plurality of mesh regions. The size of each mesh region is the same as e.g., the design size of one beam, and each mesh region serves as a pixel (unit irradiation region). The area density calculator 111 reads writing data from the storage 140, and calculates the pattern area density ρ of each pixel using the patterns defined in the writing data.

In an irradiation time calculation process (step S2), the irradiation time calculator 112 multiplies the pattern area density ρ by a reference irradiation amount DO to calculate the irradiation amount ρD0 of the beam emitted to each pixel. The irradiation time calculator 112 may further multiply ρD0 by a correction factor for correcting the proximity effect. The irradiation time calculator 112 calculates the irradiation time of each of a plurality of beams included in the multiple-beam by dividing the irradiation amount by the current density of each beam.

In an irradiation time control data generation process (step S3), the data processor 113 rearranges the irradiation time data to data for each shot with the multiple-beam in the writing sequence to generate irradiation time control data for each shot.

In a data transfer process (step S4), the writing controller 114 outputs the irradiation time control data to the deflection control circuit 130. The deflection control circuit 130 outputs the irradiation time control data to the blanking plate 204. The I/O circuit 31 of the blanking plate 204 transfers the irradiation time control data to a corresponding individual blanking mechanism 40.

In a writing process (step S5), the writing controller 114 controls the writer 150 to execute a writing process.

The writer 150 performs a writing operation by a raster scan method in which a shot beam is sequentially radiated to the pixels defined on the sample 101. A plurality of beams included in the multiple-beam simultaneously expose different pixels, and for each beam, the beam is set ON for the time defined in the irradiation time control data in order to provide a desired exposure amount to each pixel so that the pixel is irradiated with the beam in a needed irradiation amount. A beam corresponding to an exposure amount of 0 in a shot, in other words, a pixel not exposed is controlled by the blanking control to maintain in beam-off state during the shot.

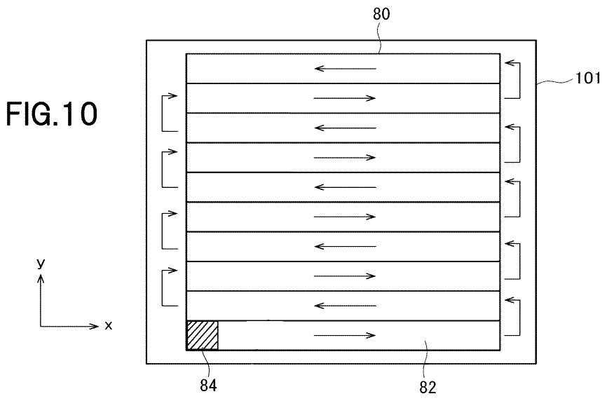

FIG. 10 is a conceptual view for explaining a writing operation with the multiple-beam 20. As illustrated in FIG. 10, a writing region 80 of the substrate 101 is virtually divided into e.g., a plurality of stripe regions 82 in a rectangular shape with a predetermined width in y direction (first direction). First, the XY stage 105 is moved, and adjustment is made so that an irradiation region (the region onto which an array of the multiple-beam 20 is projected) 84 which can be irradiated with single irradiation of the multiple-beam is located at the left end of the first stripe region 82, and writing is started.

When the first stripe region 82 is written, the XY stage 105 is moved in −x direction, thus writing proceeds relatively in +x direction. The XY stage 105 is continuously moved at a predetermined speed. After writing on the first stripe region 82 is finished, the stage position is moved in −y direction, and adjustment is made so that the beam array 84 is located at the right end of the second stripe region 82. Subsequently, the XY stage 105 is moved in +x direction, thus writing is performed in −x direction.

On the third stripe region 82, writing is performed in +x direction, and on the fourth stripe region 82, writing is performed in −x direction. The writing time can be reduced by performing writing while alternately changing the direction. Writing may be performed on each stripe region 82 in the same direction all the time, that is, one of +x direction or −x direction.

In the present embodiment, control is performed to achieve simultaneous on-beams by providing a counter value for counting up to the comparators 44 in group A, and control is performed to achieve simultaneous off-beams by providing a counter value for counting down to the comparators 44 in group B. The multiple-beam is classified into the simultaneous on-beams in group A, and the simultaneous off-beams in group B, thereby making it possible to reduce the total amount of the current of on-beam so that the influence of the Coulomb effect can be reduced and the writing accuracy can be improved. Since the number of exposure processes and the resolution of the exposure time are not changed, the above-mentioned effect can be obtained without increasing the amount of data transfer to the blanking plate 204.

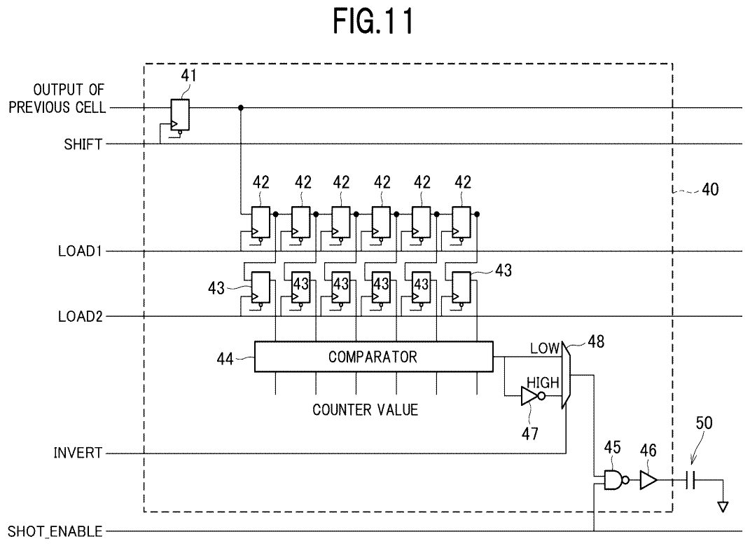

In the above embodiment, the blanking plate 204 is provided with a count-up circuit and a count-down circuit to achieve the simultaneous on-beams and the simultaneous off-beams; however, the count-down circuit (or the count-up circuit) may be omitted, and the individual blanking mechanism 40 may be provided with an inverter circuit 47 and a selector 48 as illustrated in FIG. 11.

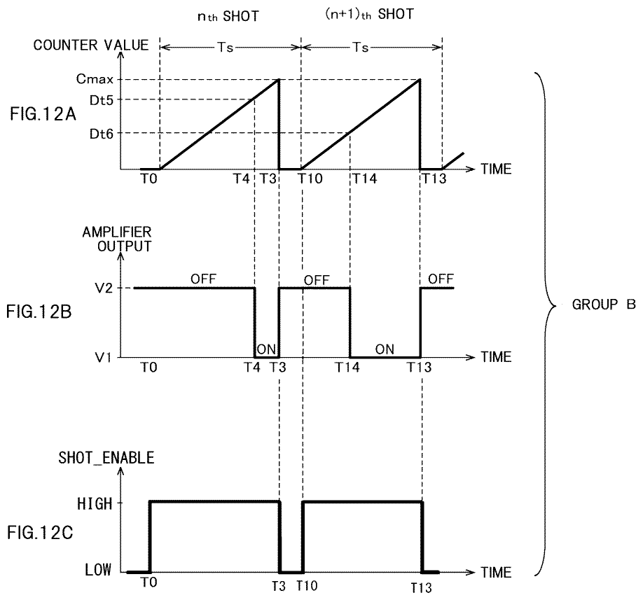

An output signal of the comparator 44, and a signal obtained by inverting the output of the comparator 44 by the inverter circuit 47 are input to the selector 48. The selector 48 outputs an either input to the NAND circuit 45 by a selection control signal (INVERT). When a counter value is input to the comparator 44 from the count-up circuit, the selector 48 selects the output of the inverter circuit 47 and provides the output to the NAND circuit 45, thus the beam controlled in the relevant cell can be switched between whether the beam is controlled as the simultaneous on-beams in group A or controlled as the simultaneous off-beams in group B. FIG. 12 illustrates an example in which by this method, a signal obtained by inverting the output of the comparator 44 by the inverter circuit 47 is output to the NAND circuit 45, and the beam controlled in the relevant cell is controlled as the simultaneous off-beams in group B.

FIG. 12A shows the change in the counter value input to the comparators 44. From time T0 to time T3, the counter value gradually increases, and the counter value is reset at time T3. Subsequently, the counter value gradually increases from time T10 to time T13. The time Ts from time T0 to time T10 corresponds to one shot cycle.

When the shot time data for the nth shot is Dt5, and the shot time data for the (n+1)th shot is Dt6, from time T0 to time T4 during which the counter value is Dt5 or less, the output of the comparator 44 is High, and the output (the output of the inverter circuit 47) of the selector 48 is Low. Thus, as illustrated in FIG. 12B, from time T0 to time T4, the output of the amplifier 46 is High (voltage V2), and the beam is in OFF state.

When the counter value exceeds Dt5 at time T4, and the output of the comparator 44 becomes Low, the output of the selector 48 becomes High, and the output of the amplifier 46 becomes Low (voltage V1), thus the beam is set ON. When the counter value is reset at time T3, SHOT_ENABLE becomes Low as in FIG. 12C, the output of the amplifier 46 becomes High, and the beam is switched to OFF. As described later, in the interval from time T3 to T10, SHOT_ENABLE is maintained at Low.

From time T3 to time T14 during which the counter value is Dt6 or less, the output of the comparator 44 is High, the output of the selector 48 is Low, the output of the amplifier 46 is High (voltage V2), and the beam is in OFF state. When the counter value exceeds Dt6 at time T14, the output of the comparator 44 becomes Low, the output of the selector 48 becomes High, the output of the amplifier 46 becomes Low (voltage V1), and the beam is set ON. In the interval from time T14 to time T13, the output of the amplifier 46 is Low (voltage V1), and the beam is in ON state. When the counter value reaches Cmax at time T13, SHOT_ENABLE is switched to Low, and the counter is reset at the same time. Since SHOT_ENABLE is Low at this point, even when the value of the counter is reset to 0, the output of the amplifier 46 becomes High, and the beam is switched to OFF.

The selector 48 of each individual blanking mechanism 40 in group B controls the output of the inverter circuit 47 to be selectively output, thus can control the corresponding beam as the simultaneous off-beams. When the selector 48 of each individual blanking mechanism 40 in group A controls the output of the comparator 44 to be selectively output, as in FIGS. 7A, 7B, the corresponding beam is controlled as the simultaneous on-beams.

The selector 48 of each individual blanking mechanism 40 in group A outputs the output signal of the comparator 44 to the NAND circuit 45, but when the counter is reset at time T3 in FIG. 12, in the interval from time T3 to T10, the selector 48 outputs High. Therefore, in the interval from time T3 to T10, when SHOT_ENABLE is High, the beams in group A are set ON. Thus, when the circuit in FIG. 11 is used, as in FIG. 12C, in the interval after completion of the nth shot until the (n+1)th shot is started, specifically, in the interval from time T3 to T10 in FIG. 12, SHOT_ENABLE needs to be maintained at Low, and during each shot, specifically, in the interval from time T0 to T3 in FIG. 12, and in the interval from time T10 to T13, SHOT_ENABLE needs to be maintained at High.

When the circuit in FIG. 6 is used, the beams in group B are controlled by a counter different from that of the beams in group A, thus as is apparent from FIG. 7, even if SHOT_ENABLE is fixed to High, in the interval after completion of the nth shot until the (n+1)th shot is started, specifically, in the interval from time T3 to T10 in FIG. 7, each beam is set OFF.

When the individual blanking mechanism 40 has a configuration as shown in FIG. 11, in group B, the time since the counter value C exceeds irradiation time control data Dt until the predetermined maximum value Cmax is reached gives the beam irradiation time. Thus, the data processor 113 generates irradiation time control data by taking such features of group B into consideration. Specifically, for group A, irradiation time control data Dt is determined to be proportional to the irradiation time. For group B, irradiation time control data Dr is determined to be proportional to the irradiation time, and irradiation time control data is determined as Dt=Cmax−Dr, where Cmax is the maximum value of the count value of the counter. Therefore, in group A, the shorter the irradiation time, the smaller the value of the irradiation time control data Dt. In contrast, in group B, the shorter the irradiation time, the greater the value of the irradiation time control data Dt.

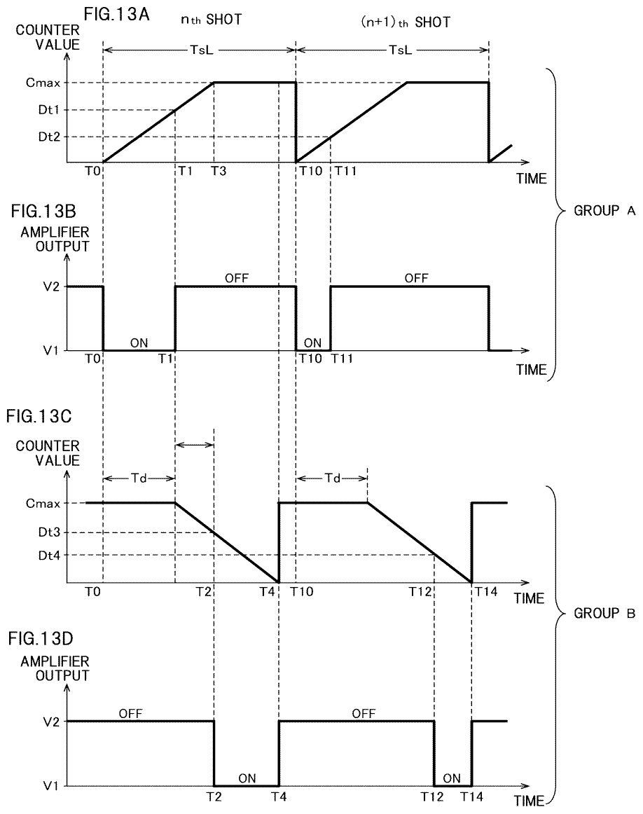

In the above embodiment, as illustrated in FIG. 7, the count start timing when the counter value of the count-up circuit starts to increase is the same as the count start timing when the counter value of the count-down circuit starts to decrease; however, as illustrated in FIG. 13, the shot cycle may be extended, and the count start timing when the counter value of the count-up circuit starts to increase may be shifted from the count start timing when the counter value of the count-down circuit starts to decrease.

FIG. 13A shows the change in the counter value input to the comparators 44 in group A. From time T0 to time T3, the counter value increases at a constant rate, and in the interval from time T3 to time T10, the counter value is constant at the predetermined maximum value Cmax. At time T10, the counter value is reset. The time TsL from time T0 to time T10 is longer than the time Ts shown in FIG. 7A.

As illustrated in FIG. 13B, from time T0 to time T1 during which the counter value is Dt1 or less, the output of the amplifier 46 is Low (voltage V1), and the beam is in ON state. In the interval from time T1 to time T10, the output of the amplifier 46 is High (voltage V2), and the beam is in OFF state.

FIG. 13C shows the change in the counter value input to the comparators 44 in group B. The count is started after lapse of time Td since time T0, and the counter value decreases at a constant rate. At time T4, the counter value is reset. Subsequently, in the interval from time T10 until time Td elapses, the counter value is constant at the predetermined maximum value Cmax.

As illustrated in FIG. 13D, from time T0 to time T2 during which the counter value is greater than Dt3, the output of the amplifier 46 is High (voltage V2), and the beam is in OFF state. When the counter value becomes Dt3 or less at time T2, the output of the amplifier 46 becomes Low (voltage V1), and the beam is set ON. In the interval from time T2 to time T4, the output of the amplifier 46 is Low (voltage V1), and the beam is in ON state. When the counter value is reset at time T4, the output of the amplifier 46 becomes High, and the beam is switched to OFF.

In the nth shot, time T0 to T1 during which the beams in group A are ON does not overlap with time T2 to T4 during which the beams in group B are ON, thus both beams are not ON simultaneously.

In this manner, the shot cycle is extended, and the count start timing for the count-up circuit is shifted from the count start timing for the count-down circuit, thus although the writing time is extended, as compared to when the shot cycle is not extended, the total value of on-beam current can be further decreased, and the writing accuracy can be further improved.

In the above embodiment, an example has been described, in which the multiple-beam is classified into simultaneous on-beams and simultaneous off-beams; however, the multiple-beam may be classified into multiple groups, and the total value of on-beam current may be reduced by shifting the count start timing for the count-up circuit in each group.

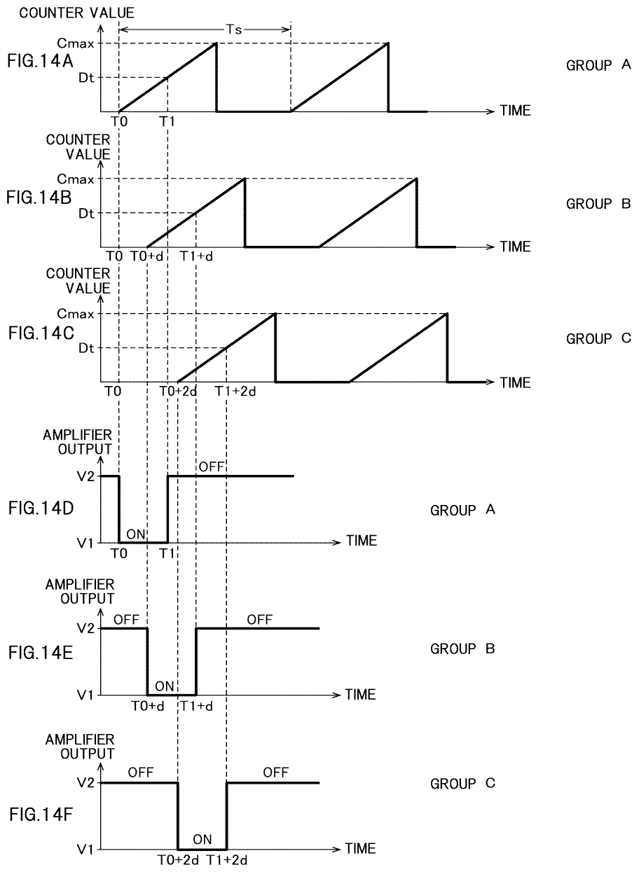

For example, the multiple-beam is classified into three groups, groups A to C, and as illustrated in FIG. 14A to FIG. 14C, the count start timing for the counter value to be input to the comparators 44 in each group is shifted by time d. For example, the count is started at time T0 in group A, the count is started at time T0+d in group B, and the count is started at time T0+2d in group C.

When the value of irradiation amount control data is Dt in each group, as illustrated in FIG. 14D, in group A, in the interval from time T0 to time T1, the beam is set ON. As illustrated in FIG. 14E, FIG. 14F, in the interval from time T0+d to time T1+d in group B, the beam is set ON, and in the interval from time T0+2d to time T1+2d in group C, the beam is set ON. In short, the timing when the beam changes from OFF to ON is shifted in each group. The total value of on-beam current can be reduced by shifting the count start timing for the count-up circuit in each group. In the embodiment, in order to shift the count start timing for the counter in each group, a shot cycle needs to be extended to complete the exposure of the beams in all groups in the shot cycle. In the example of FIG. 14, the shot cycle needs to be extended by 2d. Thus, in the embodiment, the shift amount for the count start timing in each group is set before writing, and accordingly, the shot cycle length enabling writing of all beams to be completed needs to be calculated and set.

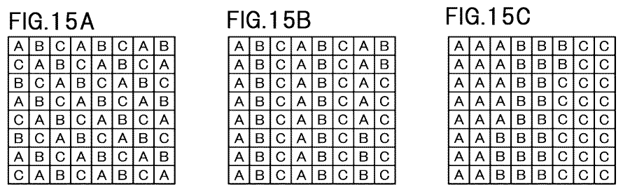

An example of classifying the beams into groups A to C is shown in FIG. 15A to FIG. 15C. For illustration purposes, FIG. 15A to FIG. 15C illustrate 8×8 beam arrays. It is preferable to classify the beams so that deviation of the beam current of on-beam does not occur. Therefore, as shown in FIG. 15A, FIG. 15B, it is preferable that the beams in groups A to C be classified so as to be disposed in order rather than being grouped as shown in FIG. 15C.

In the above embodiment, the count start timing for the count-up circuit is shifted in each group; however, in the case of a blanking plate including a count-down circuit instead of a count-up circuit, the same effect as in the above embodiment can be obtained by shifting the count start timing so that the timing for reset of the count-down circuit in each group is shifted, in other words, the timing when the beams change from ON to OFF is shifted in each group.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multiple charged particle beam writing apparatus comprising:
an emitter configured to emit multiple-beam of charged particles; and
an irradiation time controller configured to control an irradiation time of each of a plurality of beams included in the multiple-beam, wherein the plurality of beams are classified into a plurality of groups including a first group and a second group, and
the irradiation time controller controls beams in the first group to be ON simultaneously at a first timing, and to be OFF after lapse of an irradiation time of each beam, and controls beams in the second group to be ON based on the irradiation time of each beam, and to be OFF simultaneously at a second timing.

2. The multiple charged particle beam writing apparatus according to claim 1,
wherein the irradiation time controller includes individual blanking control circuits each for corresponding one of the beams, the individual blanking control circuits including an irradiation time storage that stores an irradiation time of each of the beams, and a comparator that compares an output value of a counter with the irradiation time of each of the beams,
the individual blanking control circuits corresponding to the beams in the first group are connected to a count-up circuit, and
the individual blanking control circuits corresponding to the beams in the second group are connected to a count-down circuit.

3. The multiple charged particle beam writing apparatus according to claim 1,
wherein the irradiation time controller includes individual blanking control circuits each for corresponding one of the beams, the individual blanking control circuits including an irradiation time storage that stores an irradiation time of each of the beams, and a comparator that compares an output value of a counter with the irradiation time of each of the beams,
at least part of the individual blanking control circuits further includes an inverter that inverts an output of the comparator,
the individual blanking control circuits corresponding to the beams in the first group perform blanking control using the output of the comparator, and
the individual blanking control circuits corresponding to the beams in the second group perform blanking control using an output of the inverter.

4. A multiple charged particle beam writing apparatus comprising:
an emitter configured to emit multiple-beam of charged particles; and
an irradiation time controller configured to control an irradiation time of each of a plurality of beams included in the multiple-beam,
wherein the plurality of beams are classified into a plurality of groups,
the irradiation time controller sets a shift amount for timing of a shot for each of the plurality of groups, and a shot cycle in common with the plurality of groups, and switches the beams from OFF to ON or from ON to OFF at different timings for each of the groups, and controls the irradiation time of each of the beams.

5. A multiple charged particle beam writing method comprising:
emitting a multiple-beam of charged particles;
determining pixels in a writing region on a substrate according to a pattern arrangement, and an irradiation amount for each of the pixels;
determining, for each of the pixels, an irradiation time when the pixel is irradiated with the beam based on an intensity of the beam;
adjusting an irradiation position of the multiple-beam to the pixel; and
controlling the irradiation time of each beam in the multiple-beam using a blanking device that switches between ON and OFF of the beam,
wherein a plurality of beams included in the multiple-beam are classified into a plurality of groups including a first group and a second group, and
ON and OFF of each beam in the multiple-beam is controlled so that beams in the first group are simultaneously set ON at a first timing, and set OFF after lapse of an irradiation time of each beam, and beams in the second group are set ON based on the irradiation time of each beam, and are simultaneously set OFF at a second timing.

6. A multiple charged particle beam writing method comprising:
emitting a multiple-beam of charged particles;
determining an irradiation amount for each of pixels in a writing region on a substrate according to a pattern arrangement, and;
determining, for each of the pixels, an irradiation time when the pixel is irradiated with the beam based on the irradiation amount;
adjusting an irradiation position of the multiple-beam to the pixel;
controlling the irradiation time of each beam in the multiple-beam using a blanking device that switches between ON and OFF of the beam; and
classifying a plurality of beams included in the multiple-beam into a plurality of groups, and setting a shift amount for ON or OFF timing of a shot for each of the groups, and a shot cycle in common with the plurality of groups,
wherein the plurality of beams are switched from OFF to ON or from ON to OFF at different timings for each of the groups, and the irradiation time of each of the beams is controlled.
